(19) United States
(12) Patent Application Publication
(10) Pub. No.: US 2024/0332148 A1
(43) Pub. Date: Oct. 3, 2024

(54) POWER MODULE WITH OVERLAPPING TERMINALS

(71) Applicant: SEMICONDUCTOR COMPONENTS INDUSTRIES, LLC, Scottsdale, AZ (US)

(72) Inventors: Atapol PRAJUCKAMOL, Thanyaburi (TH); Chee Hiong CHEW, Seremban (MY)

(73) Assignee: SEMICONDUCTOR COMPONENTS INDUSTRIES, LLC, Scottsdale, AZ (US)

(21) Appl. No.: 18/617,325

(22) Filed: Mar. 26, 2024

Related U.S. Application Data
(60) Provisional application No. 63/455,822, filed on Mar. 30, 2023.

(51) Int. Cl. H01L 23/498; H01L 21/48; H01L 23/00; H01L 23/367; H01L 23/473; H01L 25/07

(52) U.S. Cl. CPC H01L 23/49811; H01L 21/4853; H01L 23/3677; H01L 23/473; H01L 24/40; H01L 24/48; H01L 24/49; H01L 25/072; H01L 2224/40137; H01L 2224/40227; H01L 2224/48091; H01L 2224/48137; H01L 2224/48227; H01L 2224/49176

(57) ABSTRACT

A single side direct cooling (SSDC) package is disclosed for use in high-power electronic device modules in electric vehicles and industrial applications. The power modules route large currents through a set of metal power tabs instead of passing high currents through conductive layers of a direct bonded metal structure. By orienting the metal power tabs in a mini-heart design, stray inductance and resistance can both be reduced, thereby improving performance while simultaneously reducing the footprint of the high power module. In addition, wire bonds between chip assemblies in a high-power semiconductor device module can be replaced by solid metal clips that can better withstand high currents and voltages. The SSDC package incorporates the metal power tabs and provides heat dissipation via a metal base plate that includes a heat sink. The heat sink can be immersed in a cooling fluid to provide faster heat dissipation.

### CROSS-REFERENCE TO RELATED APPLICATION

This application claims the benefit of and priority to U.S. Provisional Patent Application No. 63/455,822, filed on Mar. 30, 2023, entitled “Single Side Direct Cooling (SSDC) Device,” the disclosure of which is incorporated by reference herein in its entirety.

### TECHNICAL FIELD

This description relates to assembling and packaging semiconductor device modules, semiconductor device assemblies, and semiconductor devices. More specifically, this description relates to semiconductor device modules with superior thermal performance.

### BACKGROUND

Semiconductor device assemblies, e.g., chip assemblies, that include power semiconductor devices can be implemented using multiple semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to an apparatus, including: a direct bonded metal substrate; a first power tab electrically coupled to the direct bonded metal substrate; a second power tab electrically coupled to the direct bonded metal substrate; a distal end of the first power tab aligned with a first longitudinal axis; and a distal end of the second power tab aligned with a second longitudinal axis non-parallel to the first longitudinal axis, the first power tab having a proximal end overlapping a proximal end of the second power tab, wherein the distal end of the first power tab does not overlap the distal end of the second power tab.

In some aspects, the techniques described herein relate to an apparatus, further including a heat transfer mechanism coupled to the direct bonded metal substrate.

In some aspects, the techniques described herein relate to an apparatus, further including at least two semiconductor dies electrically coupled via a wire bond or a clip.

In some aspects, the techniques described herein relate to an apparatus, further including an output tab electrically coupled to the direct bonded metal substrate.

In some aspects, the techniques described herein relate to an apparatus wherein, in operation, current flows from the first power tab to the output tab and from the output tab to the second power tab without flowing through the direct bonded metal substrate.

In some aspects, the techniques described herein relate to an apparatus, further including heat dissipating pins that are oriented perpendicular to a plane of the direct bonded metal substrate and a plane of the first power tab and the second power tab.

In some aspects, the techniques described herein relate to an apparatus, wherein a thickness of the first power tab and the second power tab is about three times greater than a thickness of a current path within a conductive layer of the direct bonded metal substrate.

In some aspects, the techniques described herein relate to an apparatus, further including a first opening in the distal end of the first power tab and a second opening in the distal end of the second power tab.

In some aspects, the techniques described herein relate to an apparatus, wherein a perimeter of the first power tab and the second power tab forms a heart shape.

In some aspects, the techniques described herein relate to an apparatus, including: a direct bonded metal substrate; a metal base plate attached to a bottom layer of the direct bonded metal substrate; an array of heat dissipating pins attached to the metal base plate; a first metal tab and a second metal tab coupled to the direct bonded metal substrate, the first metal tab oriented in a transverse direction with respect to the second metal tab; and a plastic case surrounding a top layer of the direct bonded metal substrate.

In some aspects, the techniques described herein relate to an apparatus, wherein the plastic case is attached to the metal base plate without screws.

In some aspects, the techniques described herein relate to an apparatus, further including power tabs extending over the direct bonded metal substrate.

In some aspects, the techniques described herein relate to an apparatus, wherein the first metal tab includes a negative terminal, and the second metal tab includes a positive terminal, and further including a third metal tab including an output terminal opposite the first metal tab and the second metal tab.

In some aspects, the techniques described herein relate to an apparatus, wherein the apparatus is configured for current to flow from the positive terminal to the output terminal and back to the negative terminal via a central region of the direct bonded metal substrate.

In some aspects, the techniques described herein relate to an apparatus, wherein the first metal tab is oriented at a right angle with respect to the second metal tab.

In some aspects, the techniques described herein relate to a method, including: overlapping proximal ends of a first power tab and a second power tab coupling clips of the first power tab to a central region of a substrate; coupling clips of the second power tab to an edge region of the substrate; and coupling clips of a third power tab to the central region of the substrate.

In some aspects, the techniques described herein relate to a method, wherein the first power tab, the second power tab, and the third power tab are configured as integral elements of a plastic case.

In some aspects, the techniques described herein relate to a method, wherein coupling the clips of the first power tab and the clips of the third power tab to a central region of the substrate includes overlaying the clips above circuitry on the substrate by positioning the plastic case relative to the substrate.

In some aspects, the techniques described herein relate to a method, wherein the overlapping includes aligning a first hole in the first power tab with a second hole in the second power tab to produce aligned first and second holes.

In some aspects, the techniques described herein relate to a method, further including attaching a heat dissipating pin to the substrate, wherein the heat dissipating pin extends through the aligned first and second holes.

### BRIEF DESCRIPTION OF THE DRAWINGS

FIG. 1 is a pictorial perspective view of a power module, according to implementations of the present disclosure.

FIGS. 2A and 2B illustrate two different options for a circuit layout on a direct bonded metal (DBM) structure, according to implementations of the present disclosure.

FIGS. 3A and 3B illustrate a circuit model for a power module, according to implementations of the present disclosure.

FIG. 4 is a magnified view of a DBM structure, according to implementations of the present disclosure.

FIG. 5A is a top perspective view of a single side direct cooling (SSDC) package, according to implementations of the present disclosure.

FIG. 5B is a bottom perspective view of a single side direct cooling (SSDC) package, according to implementations of the present disclosure.

FIG. 6A is a magnified cross-sectional view of a clip assembly, according to implementations of the present disclosure.

FIG. 6B reproduces FIG. 5B,

FIG. 7 is a top perspective view of the SSDC package housing three power modules that include wire bond versions of a circuit layout on a DBM, according to implementations of the present disclosure.

FIG. 8 is a top perspective view of the SSDC package housing three power modules that include clip versions of a circuit layout on a DBM, according to implementations of the present disclosure.

FIG. 9A reproduces FIG. 7.

FIG. 9B is a magnified view of a thermistor, according to implementations of the present disclosure.

FIG. 10 illustrates a computer model of a fluid-cooled SSDC package housing three power modules, according to implementations of the present disclosure.

FIG. 11 is a pictorial perspective view of a fluid-cooled SSDC package housing three power modules, according to implementations of the present disclosure.

FIG. 12 is a flow diagram for a method of constructing a power module, according to implementations of the present disclosure.

FIG. 13 is an exploded view of an SSDC package for high-power electronic device modules, according to implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

The footprint of electronic devices is important with respect to materials cost and reliability. When electronic devices, e.g., high-power semiconductor device modules, are laid out in an inefficient manner, wasted space on a substrate increases material cost unnecessarily. In addition, wiring between devices that are spaced apart can be inherently more vulnerable to damage or breakage and, consequently, can cause reliability failures. These concerns are particularly significant for high power modules that include expensive materials such as silicon carbide (SiC), high tech ceramics made of silicon nitride (Si3N4), and direct bond metal (DBM) structures, e.g., direct bond copper (DBC) structures used as substrates for the high power modules. When these high power modules are manufactured in large volume, even a small reduction in per unit cost can add up to a substantial saving.

This disclosure relates to implementations of a single side direct cooling (SSDC) package for high-power electronic device modules. The power modules route large currents through a set of metal power tabs instead of passing high currents through a DBM structure. The metal power tabs are about three times thicker than conductive layers that form a current path through the DBM structure. By orienting the power tabs in a mini-heart design, stray inductance and resistance can both be reduced, thereby improving performance while simultaneously reducing the footprint of the high power module. In addition, wire bonds between chip assemblies in a high-power semiconductor device module can be replaced by solid metal clips that can better withstand high currents and voltages. The SSDC package incorporates the metal power tabs and provides heat dissipation via a metal base plate that includes a heat sink. The heat sink can be immersed in a cooling fluid to provide faster heat dissipation.

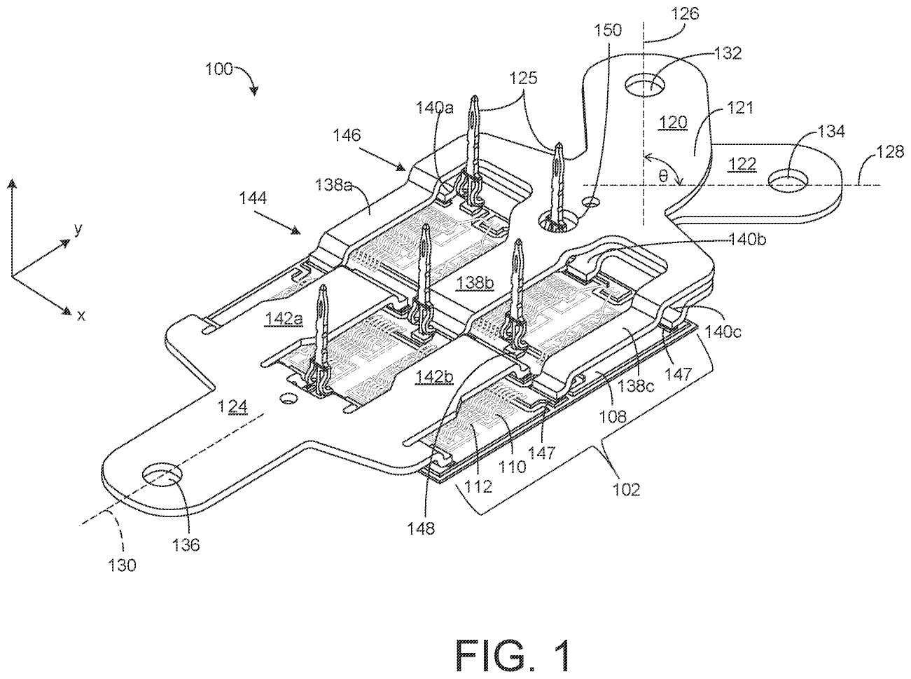

FIG. 1 is a pictorial perspective view of a power module 100, in accordance with some implementations of the present disclosure. The power module 100 provides electrical connectivity for high-power semiconductor devices mounted on a DBM 102. The power module 100 can also provide mechanical stability and protection for the high-power semiconductor devices, as well as heat dissipation.

In some implementations, the DBM 102 is a multi-layer substrate to which various electronic assemblies are mounted, e.g., attached. The DBM 102 includes a die attach pad (DAP) 108 and one or more electronic components, e.g., semiconductor dies or chip assemblies 110 in contact with the DAP 108. The chip assemblies 110 may include high power chip assemblies that generate heat and may cause heat accumulation within the DBM 102. The chip assemblies 110 are electrically coupled to one another by wire bonds 112. Some of the wire bonds 112 may extend through the DAP 108 to make external connections to the chip assemblies 110. The wire bonds 112 can include copper wires and/or aluminum wires. The DAP 108 can be integral to, or attached to, a first conductive layer of the DBM 102. The DBM 102 can further include a second conductive layer and a non-conductive layer (not shown).

In some implementations, the DBM 102 can be a direct bond copper (DBC) type structure, a direct plating copper (DPC) type structure, or a direct bond aluminum (DBA) type structure. The DBM 102 may be referred to as a heat spreader that provides single-sided cooling of the chip assemblies 110. In some implementations, the DBM 102 can have a total thickness in a range of about 0.5 mm to about 3.0 mm. In some implementations, the DBM 102 is designed as a three-layer DBM structure that includes the non-conductive layer sandwiched between the first conductive layer and the second conductive layer. In some implementations, the non-conductive layer serves as a thermal mass disposed between the two outer metal layers to draw in and absorb heat. The non-conductive layer may also provide electrical insulation between the first conductive layer and the second conductive layer of the DBM 102.

In some implementations, the first conductive layer and the second conductive layer of the DBM 102 can be, or can include, a metal layer (e.g., a copper layer, a copper alloy layer) that is formed on (e.g., bonded to, sputtered on, diffused onto to, heat-formed on) the non-conductive layer. The first conductive layer can be coupled to a first side of the non-conductive layer, and the second conductive layer can be coupled to a second side of the non-conductive layer. The first conductive layer can be, or can include, a metal trace as the die attach pad (DAP) 108 on which to mount (or couple) the chip assemblies 110. The first conductive layer or the second conductive layer can be referred to as an upper conductive layer or as a lower conductive layer depending on the orientation of the device. In some implementations, the non-conductive layer of the DBM 102 can include a ceramic material, e.g., silicon nitride (Si3N4) or aluminum oxide (Al2O3), Si3N4 being a significantly more expensive ceramic material than Al2O3.

In some implementations, the die attach pad 108 can be formed by the first conductive layer, e.g., a top conductive layer, of the DBM 102. In some implementations, the non-conductive layer and/or the second conductive layer of the DBM 102 can have a larger footprint than the DAP 108.

The chip assemblies 110 can be attached to, e.g., mounted on, or coupled to, a top surface of the DAP 108 by a copper sputtering process or by a bonding agent, e.g., an epoxy, a solder, a silver (Ag) sintering material, and/or an adhesive. In some implementations that include multiple chip assemblies 110, first and second chip assemblies 110 can be coupled to the DAP 108 by two different bonding agents. For example, in some implementations, a first chip assembly 110 can be attached to the DAP 108 by sintering, while a second chip assembly 110 is attached to the DAP 108 by polyimide tape.

In some implementations that include multiple chip assemblies, the chip assemblies 110 can include, for example, high power semiconductor devices such as an insulated gate bipolar transistor (IGBT) and a controller configured to control the IGBT. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. In some implementations, other types of semiconductor dies, e.g., MOSFETs, diodes, and so forth, can be used as one or more of the chip assemblies 110. In some implementations, fast recovery diodes (FRDs) may be used in conjunction with power transistors.

The chip assemblies 110 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In general, any type of semiconductor chip can be fabricated on any type of substrate.

In some implementations, different chip assemblies 110 can be fabricated on different substrates in a hybrid configuration. For example, an IGBT chip assembly 110 can be fabricated on a SiC substrate, while a controller chip assembly 110 can be fabricated on a silicon substrate. In some implementations as described herein, multiple chip assemblies 110 can be fabricated on the same substrate, e.g., on a SiC substrate, suitable for high power applications.

In some implementations, the power module 100 can include a first power tab 120, a second power tab 122, a third power tab 124, and heat dissipating pins 125 (5 shown). In some implementations, the power tabs 120, 122, and 124 can be made of a thick metal, about 1.0 mm thick, capable of supporting high voltages in a range of about 600 V to about 1700 V and carrying high currents up to about 900 A. In some implementations, the first power tab 120 and the second power tab 122 are disposed on one end of the DBM 102 and the third power tab 124 is disposed on the other end of the DBM 102. In operation, the first power tab 120 can be coupled to a negative direct current terminal (DC−), the second power tab 122 can be coupled to a positive direct current terminal (DC+), and the third power tab 124 can be an output terminal, so that current flows from the second power tab 122 to the third power tab 124, and from the third power tab 124 to the first power tab 120. In the power module 100, current is routed mainly through the power tabs 120 and 124 rather than through the DBM 102. In some implementations, resistance of the power tabs can be about 58% less than resistance in the DBM 102. In some implementations, one or more of the first power tab 120, the second power tab 122, and the third power tab 124 can have rounded ends. The rounded ends can reduce a concentration of electric charge during operation of the power module 100. In some implementations, the power tabs 120, 122, and 124 can have square ends, tapered ends, or ends having another shape.

In some implementations, a proximal end of the first power tab 120 can be aligned with, e.g., can extend in a same direction as, a first longitudinal axis 126; a proximal end of the second power tab 122 can be aligned with a second longitudinal axis 128; and a proximal end of the third power tab 124 can be aligned with a third longitudinal axis 130. A longitudinal axis represents the direction in which the length, e.g., the longest linear dimension, of the power tab extends. In some implementations, the third longitudinal axis 130 can be aligned with a length of the DBM 102, e.g., in the y-direction, as shown in FIG. 1.

In some implementations, the first longitudinal axis 126 and the second longitudinal axis 128 can be rotated with respect to the third longitudinal axis 130, for example, at about a 45 degree angle as shown in FIG. 1, or at some other acute angle so that the longitudinal axes are non-parallel. In some implementations the second longitudinal axis 128 can be oriented at an angle θ with respect to the first longitudinal axis 126, wherein the angle θ is symmetric about the third longitudinal axis 130 so that the third longitudinal axis 130 bisects the angle θ. In some implementations, the angle θ is approximately 90 degrees such that the proximal ends of the first power tab 120 and the second power tab 122 extend out from the DBM 102 in different directions that are orthogonal to each other. In some implementations, as seen from a top-down view, the first power tab 120 overlaps the second power tab 122 such that a perimeter of the first power tab and the second power tab forms a heart shape in the x-y plane. In some implementations, and as shown in this implementation, a curved portion 121 of the first power tab 120 is disposed over a portion of the second power tab 122 (when viewed from a top-down view). In some implementations (and not shown in this view), a curved portion of the second power tab 122 can be disposed over a portion of the first power tab 120 (when viewed from a top-down view).

In some implementations, the angle θ is less than 90 degrees, or greater than 90 degrees, such that the proximal ends of the first power tab 120 and the second power tab 122 extend out from the DBM 102 in different directions that are not orthogonal to each other. The angle θ determines the amount of overlap between the proximal ends of the first power tab 120 and the second power tab 122. As the angle θ approaches 0, the overlap area between the first and second power tabs 120 and 122 will approach 100%; as the angle θ approaches 180 degrees, the overlap area between the first and second power tabs 120 and 122 will approach zero. The overlap area can affect the size, form factor, packaging, and usage of the power module 100. The overlap may also affect current flow through the power module 100.

It may be desirable to maximize the overlap area of the first power tab 120 and the second power tab 122 to reduce, e.g., minimize, stray inductance and thermal resistance during high frequency operation of the power module 100. In some implementations, it may be desirable to reduce stray inductance below, for example, about 8 nH, and junction-to-fluid thermal resistance, Rthjf, below about 0.1 degree C. per Watt. Use of the power module 100 can reduce stray inductance by about 40% relative to other designs.

An opening 132, e.g., a hole, can be formed in the proximal end of the first power tab 120; an opening 134 can be formed in the proximal end of the second power tab 122; and an opening 136 can be formed in the proximal end of the third power tab 124. The openings 132, 134, and 136 can accommodate fasteners, e.g., screws, for coupling the respective power tabs 120, 122, and 124 to sources of power, e.g., high voltage battery terminals. The openings 132, 134, and 136 can also help to accelerate heat dissipation. by increasing the surface area of the first power tab 120, the second power tab 122, and the third power tab 124, respectively. The openings 132, 134, and 136 are shown as round holes as an example, but the openings can have any shape.

In some implementations, a distal end of the first power tab 120 can include a first set of clips 138 (three shown, 138a, 138b, and 138c); a distal end of the second power tab 122 can include a second set of clips 140 (three shown, 140a, 140b, and 140c); and a distal end of the third power tab 124 can include a third set of clips 142 (two shown, 142a and 142b). The first set of clips 138 extend over the chip assemblies 110 and wire bonds 112 to a center region 144 of the DBM 102, where the first set of clips 138 couple the first power tab 120 to the DAP 108. Likewise, the third set of clips 142 can extend over the chip assemblies 110 and wire bonds 112 to the center region 144 of the DBM 102, where the third set of clips 142 couple the third power tab 124 to the DAP 108. The second set of clips 140 couple the second power tab 122 to an end region 146 of the DAP 108. The second set of clips 140 can therefore have shorter lengths compared with the first set of clips 138 and the third set of clips 142. In some implementations, the widths of the outside clips 138a and 138c can be narrower than the width of the inside clip 138b, which is placed in the center of the DBM 102.

In some implementations, the clips 138 extend parallel to one another in the −y direction as do the clips 140, which are disposed under the clips 138.

The center region 144 and the end region 146 of the DBM 102 can include solder pads 147 that provide electrical connections to circuitry that distributes electrical power delivered by the clips 138, 140, and 142. In some implementations, the clips 138, 140, and 142 can be connected to the DAP 108, e.g., a top conductive layer of the DBM 102, by other methods such as ultrasonic welding. Placement of the clips 138 and 142, or placement of the solder pads 147, can alternate, e.g., be interdigitated, within the center region 144 to make efficient use of space on the DAP 108. In some implementations, the clips 142 are wider than the clips 138. Consequently, the solder pads 147 may be sized differently to match footprints of the various clips.

In some implementations, the heat dissipating pins 125 can extend in a direction perpendicular to the plane of the DBM 102, e.g., in the z-direction. Each of the heat dissipating pins 125 can be attached to the DAP 108 by a platform 148. The heat dissipating pins 125 can be metallic. In some implementations, one or more of the heat dissipating pins 125 can extend through an opening 150 in the first power tab 120. The opening 150 can also extend through an opening in the overlapping second power tab 122 that is aligned with the opening 150.

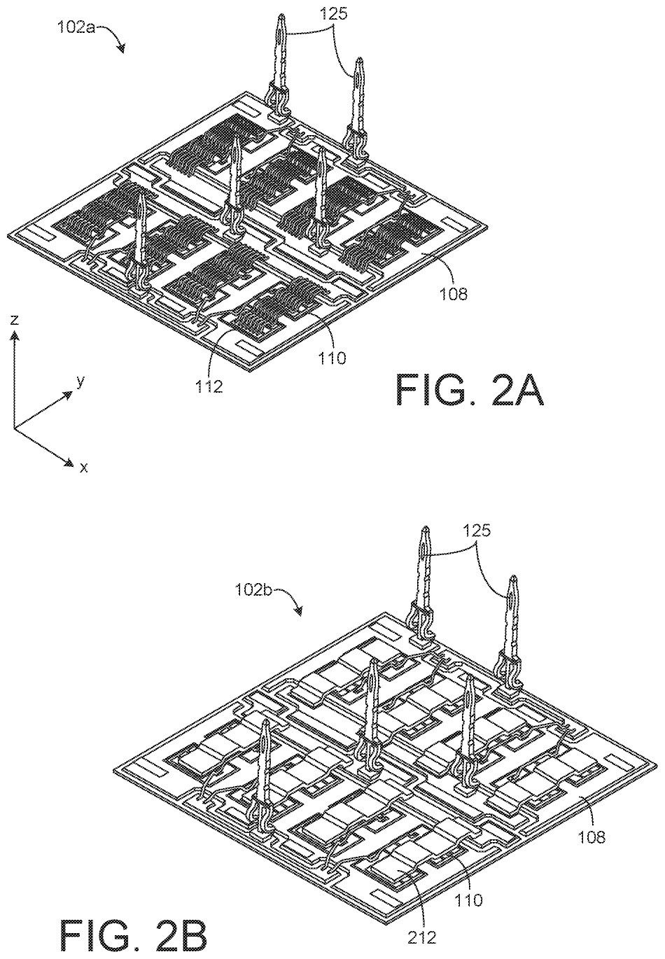

FIGS. 2A and 2B show two different options for a circuit layout on the DBM 102, in accordance with some implementations of the present disclosure. A wire bond version 102a is FIG. 2A (also in FIG. 1) and a clip version 102b, is shown in FIG. 2B. The wire bond version 102a includes wire bonds 112 that provide connections between adjacent chip assemblies 110, and between the DAP 108 and the chip assemblies 110; the clip version 102b includes clips 212 that provide connections between adjacent chip assemblies 110, and between the DAP 108 and the chip assemblies 110. The clips 212 can be made of a solid, continuous conducting material, e.g., copper, aluminum, or other metal. The clips 212 may support currents and voltages that exceed current and voltage ratings for the wire bonds 112. In both versions, the wire bond version 102a and/or the clip version 102b can be implemented as a single die having a die size, e.g., die area, of about 22 mm2, about 25 mm2, about 27 mm2, or about 32.4 mm2. In some implementations, the wire bond version 102a may be used for certain types of chip assemblies 110 while the clip version 102b may be used for other types of chip assemblies 110. The same type and placement of heat dissipating pins 125 can be used in both the wire bond version 102a and the clip version 102b of the DBM 102.

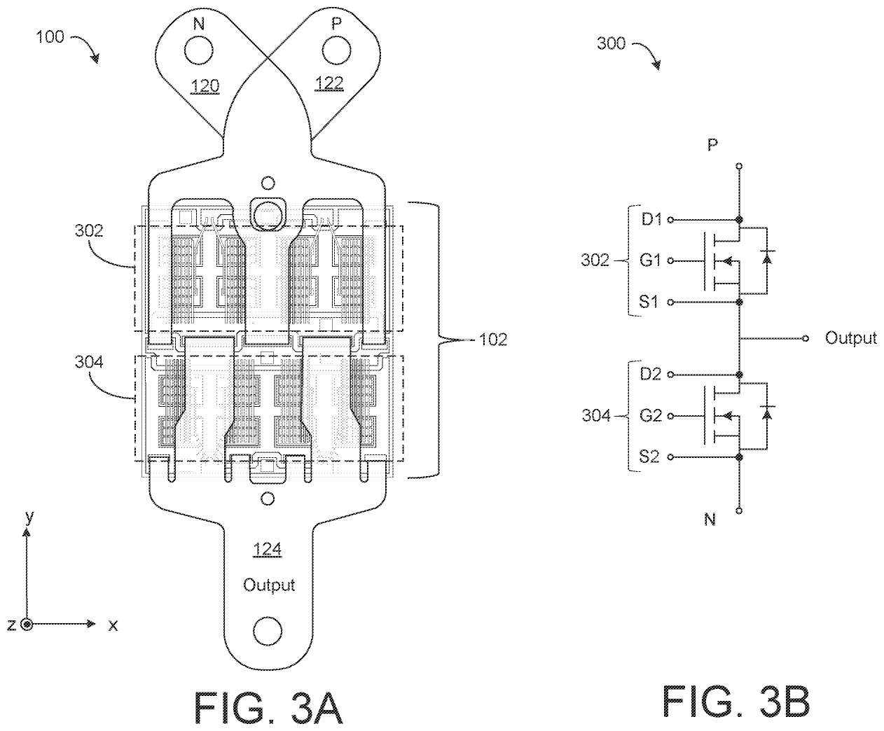

FIGS. 3A and 3B illustrate a circuit model 300 of the power module 100, in accordance with some implementations of the present disclosure. FIG. 3A represents an upper half of the DBM 102 as a high side switch 302 coupling the positive terminal at the second power tab 122 to the output at the third power tab 124. FIG. 3A further represents a lower half of the DBM 102 as a low side switch 304 coupling the negative terminal at the first power tab 120 to the output at the third power tab 124. FIG. 3B shows the high side switch 302 can be modeled as a first MOSFET coupled between a positive terminal P and an output terminal. The first MOSFET includes a source terminal S1, a drain terminal D1, and a gate terminal G2. FIG. 3B further shows the low side switch 304 can be modeled as a second MOSFET coupled between a negative terminal N and the output terminal. The second MOSFET includes a source terminal S2, a drain terminal D2, and a gate terminal G2.

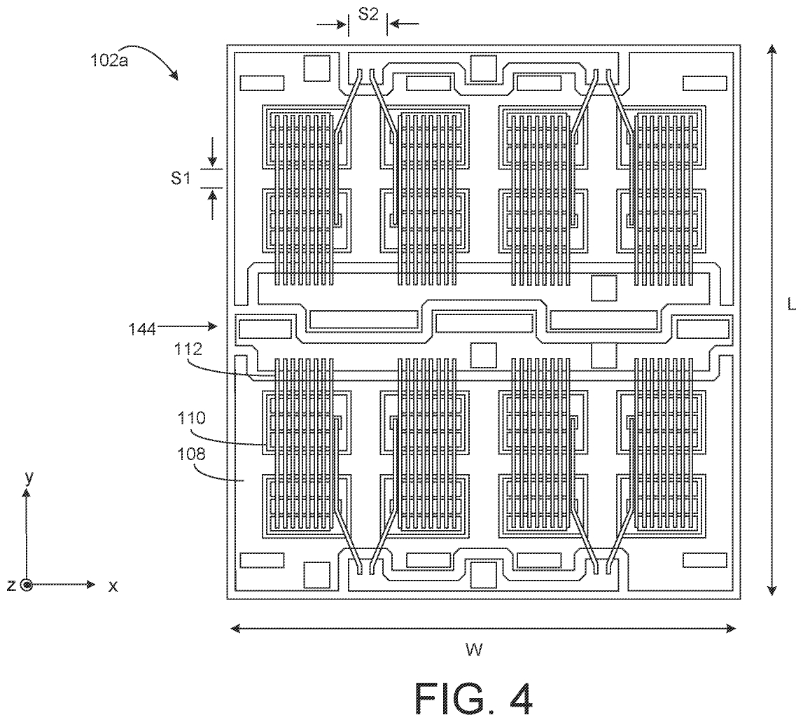

FIG. 4 is a magnified view of the DBM 102, in accordance with some implementations of the present disclosure. The magnified view in FIG. 4 is of the wire bond version 102a, showing details of the DAP 108, the chip assemblies 110, the wire bonds 112, and the center region 144. In some implementations, the layout of the chip assemblies 110 and the wire bonds 112 is replicated symmetrically in both halves of the DBM 102, with 8 chip assemblies 110 in each half. In some implementations, the DBM 102 on which the chip assemblies 110 are mounted is in the form of a direct bonded copper (DBC) structure. An efficient layout of components within the available surface area of the DBC structure can reduce costs, e.g., the cost of copper material, by as much as 33%. An efficient layout is facilitated by not having to rely on power being transmitted by the conductive layers of the DBC. Spacing between the chip assemblies 110 can affect the thermal performance of the power module 100. In some implementations, a vertical spacing S1 in the y-direction separating rows of chip assemblies 110 can be in a range of about 2.0 mm to about 2.4 mm, and a horizontal spacing S2 in the x-direction separating columns of chip assemblies 110 can be in a range of about 2.6 mm to about 3.2 mm. In some implementations, a length L of the DBM 102 is in a range of about 38 mm to about 48 mm and a width W of the DBM 102 is in a range of about 36 mm to about 44 mm.

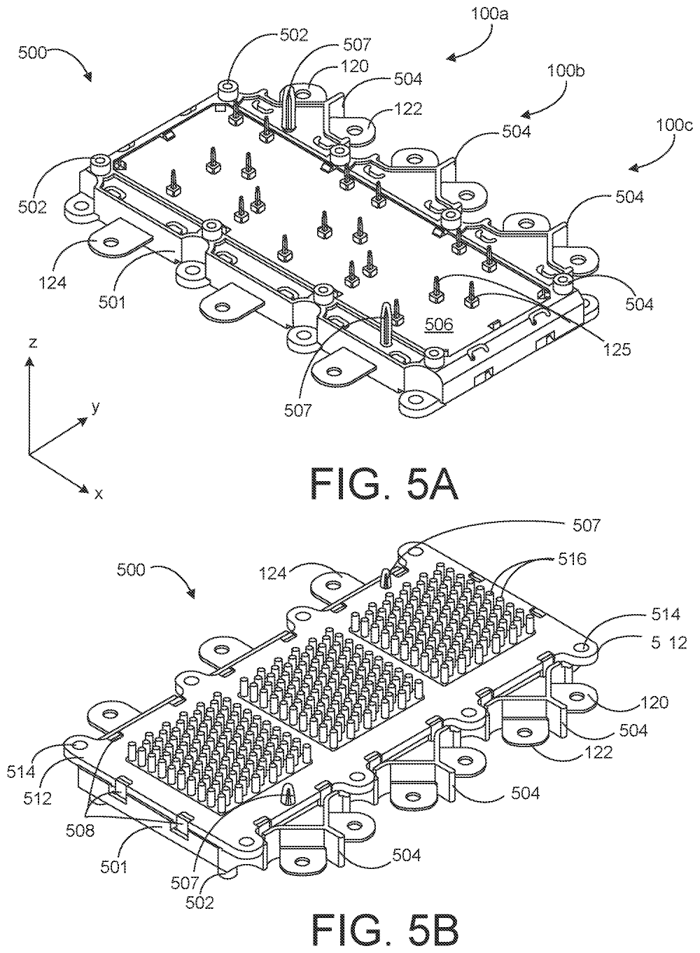

FIGS. 5A and 5B are top side and bottom side exterior views, respectively, of a single side direct cooling (SSDC) package 500, in accordance with some implementations of the present disclosure. In some implementations, three power modules 100, e.g., a first power module 100a, a second power module 100b, and a third power module 100c, can be assembled into the SSDC package 500. In some implementations, a different number of power modules 100 can be housed in the SSDC package 500.

With reference to FIG. 5A, in some implementations, a top side of the SSDC package 500 can include a plastic case 501, fasteners 502 (8 shown) and dividers 504 (3 shown). The SSDC package 500 further includes a lid 506 forming a top surface of the plastic case 501 and alignment pins 507 adjacent to, e.g., disposed on a frame of the plastic case 501, outside a perimeter of the lid 506. The plastic case 501 can be made of any polymer material that provides mechanical stability and electrical insulation between the power modules 100. The fasteners 502, e.g., thumbscrews, can be used to clamp the SSDC package 500 around the power modules 100, to secure the power modules 100 in place and form a tight seal between the lid 506 and the rest of the plastic case 501. The dividers 504 can be used to stabilize and fix the orientation of the first power tab 120 with respect to the second power tab 122 of each power module 100, so that the desired angle θ between the longitudinal axes of the power tabs is maintained as shown in FIG. 1. The dividers 504 can also provide electrical isolation between the first power tab 120 and the second power tab 122, which will be coupled to opposite polarities in operation. Use of the dividers 504 can reduce the chance of arcing, e.g., an electrical discharge, occurring between the first power tab 120 and the second power tab 122. The heat dissipating pins 125 attached to the DAP 108 of the DBM 102 within each power module 100 can extend upward through holes in the lid 506. The holes can be sealed around the heat dissipating pins 125 to ensure they are watertight. The heat dissipating pins 125 are one example of a heat transfer mechanism that is directly coupled to the DBM 102.

With reference to FIG. 5B, in some implementations, a bottom side of the SSDC package 500 further includes clips 508 (16 shown) around a bottom perimeter of the plastic case 501. The clips 508 couple the SSDC package 500 to a metal base plate 510 that functions (e.g., serves) as a heat sink for the SSDC package 500. The metal base plate 510 is another example of a heat transfer mechanism that is coupled, e.g., mechanically coupled, to the DBM 102. The metal base plate 510 can include for example, aluminum, copper, or alloys thereof (e.g., AlCu). The metal base plate 510 can include tabs 512 (8 shown) having openings 514 to accommodate fasteners used to install the SSDC package 500. In some implementations, the metal base plate 510 can include fins, e.g., an array of heat dissipating cylinders 516 positioned under each power module 100. Each one of the arrays can include, for example, a grid of about 60 heat dissipating cylinders 516, or “pin fins.” The heat dissipating cylinders 516 are another example of a heat transfer mechanism that is coupled, e.g., mechanically and thermally coupled, to the DBM 102.

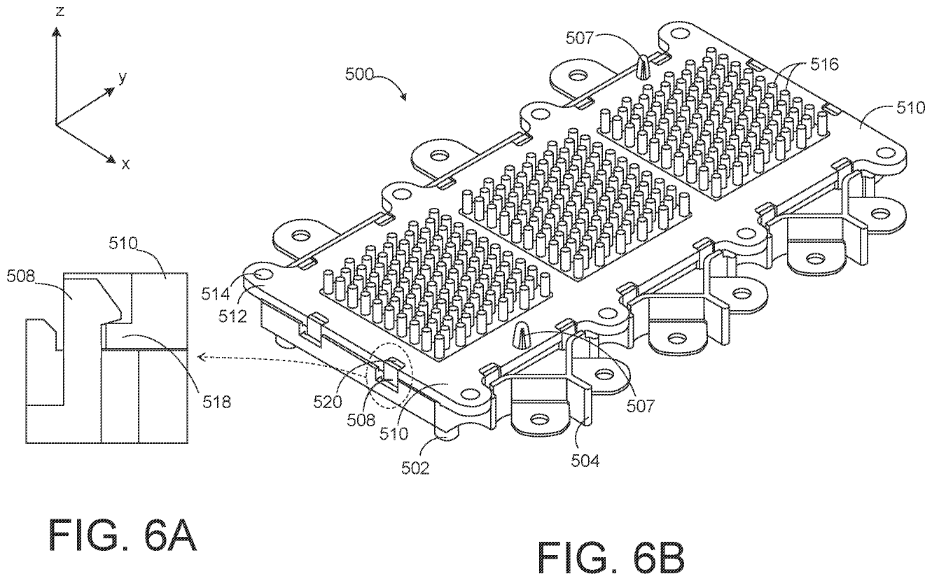

FIG. 6A shows a magnified cross-sectional view of a clip assembly, in accordance with some implementations of the present disclosure. FIG. 6B reproduces FIG. 5B. The clip assembly includes the clips 508 and an edge 518 formed within an indentation 520 of the metal base plate 510. The clips 508 can be shaped so as to interlock with the edge 518 of the metal base plate 510. Once the clip 508 has caught the edge 518, the clip 508 can be forced downward, in the −z direction, to securely hold the metal base plate 510 against the underside of the plastic case 501 to ensure the power modules 100 are safely maintained within a watertight enclosure. Use of the clips 508 to mechanically lock the plastic case 501 to the metal base plate 510 can be a substitute for using screws to attach the plastic case 501 to the metal base plate 510, thus simplifying assembly. In some implementations, an adhesive, e.g., an epoxy or other type of water-resistant glue can also be used to secure the plastic case 501 to the metal base plate 510 prior to locking the clips 508 in place.

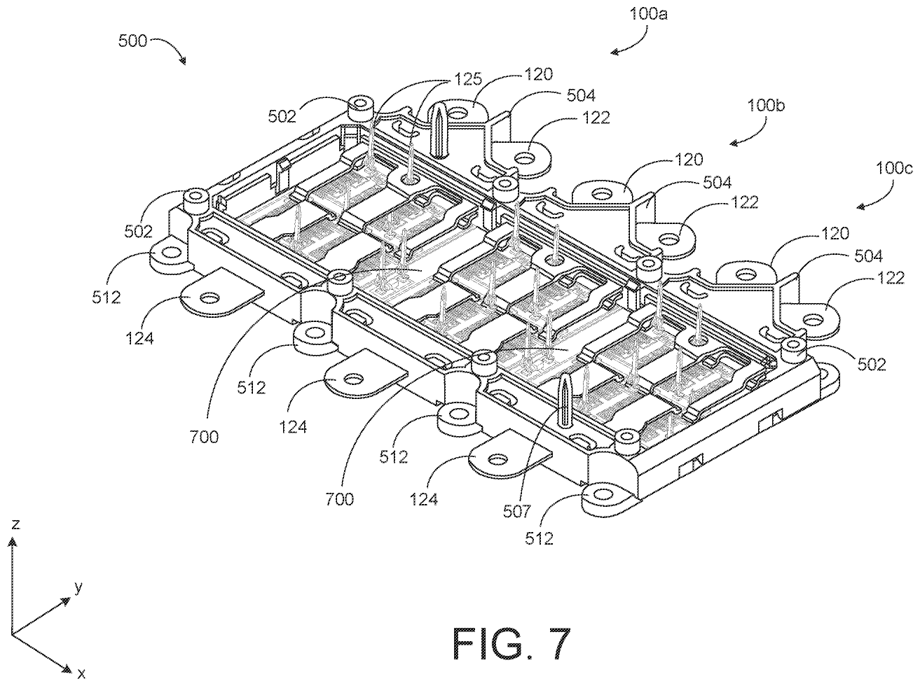

FIG. 7 is a pictorial perspective view of the top side of the SSDC package 500, in accordance with some implementations of the present disclosure. In the view shown in FIG. 7, the lid 506 is removed to expose the first power module 100a, the second power module 100b, and the third power module 100c. Each one of the power modules 100 shown in FIG. 7 is implemented with the wire bond version 102a of the DBM 102. FIG. 7 shows that the interior of the SSDC package 500, e.g., of the plastic case 501, further includes separation areas 700. The separation areas 700 of the plastic case 501 provide spacing, e.g., physical and electrical isolation, between the power modules 100 within the SSDC package 500.

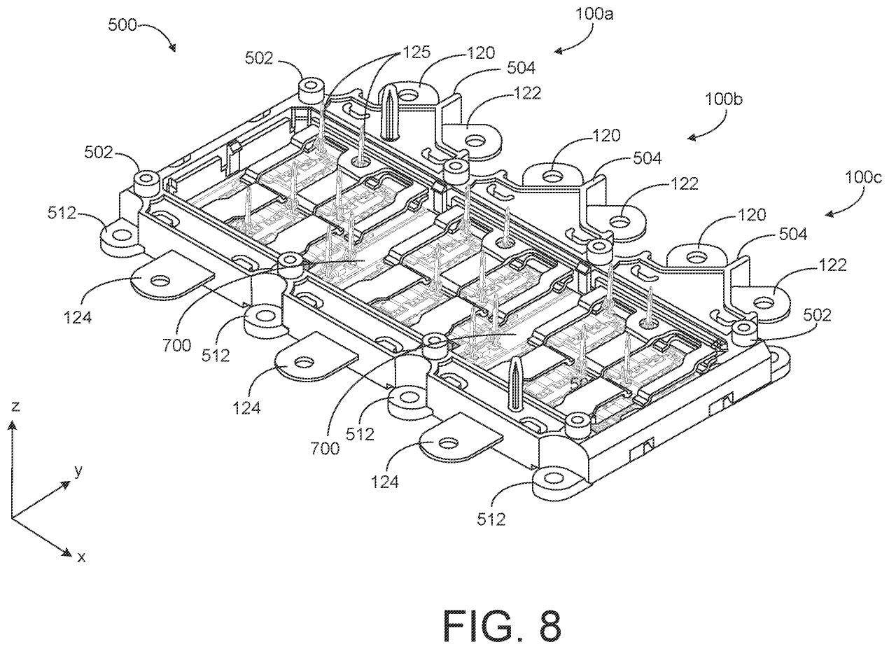

FIG. 8 is a pictorial perspective view of the top side of the SSDC package 500, in accordance with some implementations of the present disclosure. In the view shown in FIG. 8, the lid 506 is removed to expose the first power module 100a, the second power module 100b, and the third power module 100c. Each one of the power modules 100 shown in FIG. 8 is implemented with the clip version 102b of the DBM 102. Similar to FIG. 7, FIG. 8 shows that the interior of the SSDC package 500 further includes separation areas 700. The separation areas 700 of the SSDC package 500 provide spacing, e.g., physical and electrical isolation, between the power modules 100 within the SSDC package 500.

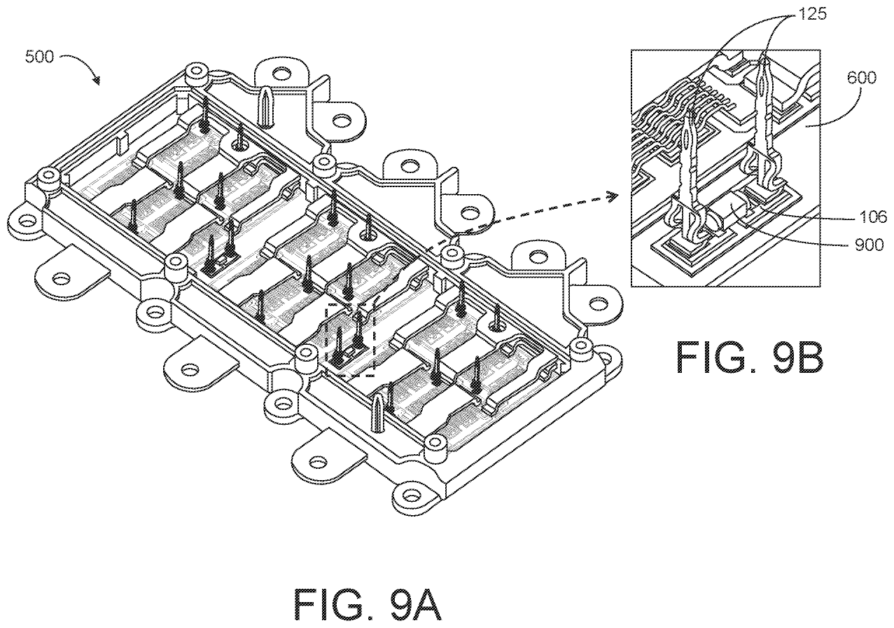

FIG. 9A reproduces FIG. 7, showing the SSDC package 500 implemented with the wire bond version 102a of the DBM 102. FIG. 9B shows a magnified view of a device, e.g., a thermistor 900, in accordance with some implementations of the present disclosure. The thermistor 900 can be disposed in the separation areas 700 of the SSDC package 500 implemented with either the wire bond version 102a or the clip version 102b of the DBM 102. The thermistor 900 can be attached to a separate DAP 108 together with heat dissipating pins 125 on either end of the thermistor 900. The thermistor 900 can be used to monitor temperature of the power modules 100 within the SSDC package 500.

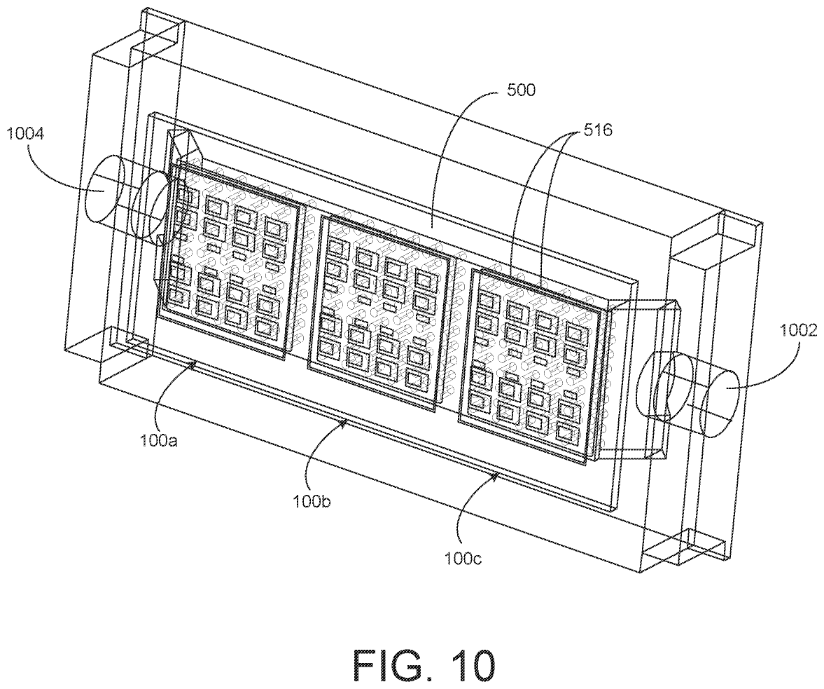

FIG. 10 illustrates a model of a cooling unit 1000, in accordance with some implementations of the present disclosure. The cooling unit 1000 is a structure, e.g., a water jacket, that can be used to surround a lower portion of the SSDC package 500 to aid in dissipating heat from the metal base plate 510. When the cooling unit 1000 is used with the metal base plate 510, the heat dissipating cylinders 516 can be equipped with O-rings (not shown) to prevent the cooling fluid from leaking into the SSDC package 500. The cooling unit 1000 is another example of a heat transfer mechanism that is coupled, e.g., mechanically and/or thermally coupled, to the DBM 102. In some implementations, the cooling unit 1000 can include a coolant inlet 1002 at the right end of the cooling unit 1000 and a coolant outlet 1004 at a left end of the cooling unit 1000. The coolant inlet 1002 can admit a flow of cooling fluid (not shown) into the cooling unit 1000. The coolant outlet 1004 can provide an exit for the cooling fluid to leave the cooling unit 1000. The cooling fluid can be, for example, water, ethylene glycol, e.g., glycol-50, or another fluid having properties suitable for absorbing heat from the metal base plate 510. In some implementations, the cooling fluid can flow through the cooling unit 1000 at a flow rate of about 7 liters per minute to about 10 liters per minute. In some implementations, the cooling fluid can be supplied to the cooling unit 1000 at a temperature of about 45 degrees C.

The cooling unit 1000 can be used to simulate potential cooling scenarios for the power modules 100 housed in the SSDC package 500. A numerical model used for the simulation can be a three-dimensional (3D) model that uses steady state thermal analysis to test different flow and heat transfer variables and compute a junction-to-fluid thermal resistance (Rthjf). A maximum Rthjf per switch and a mean Rthjf per switch can both be determined. The maximum Rthjf per switch can be computed as (Tj−Tf)/power dissipation per switch, wherein Tj is the maximum junction temperature and Tf is the fluid temperature of the cooling fluid. The mean Rthjf per switch can be computed as (Tj−Tf)/power dissipation per switch, wherein Tj is the mean junction temperature and Tf is the fluid temperature of the cooling fluid. The 3D model can be run for both the wire bond version 102a and the clip version 102b of the DBM 102.

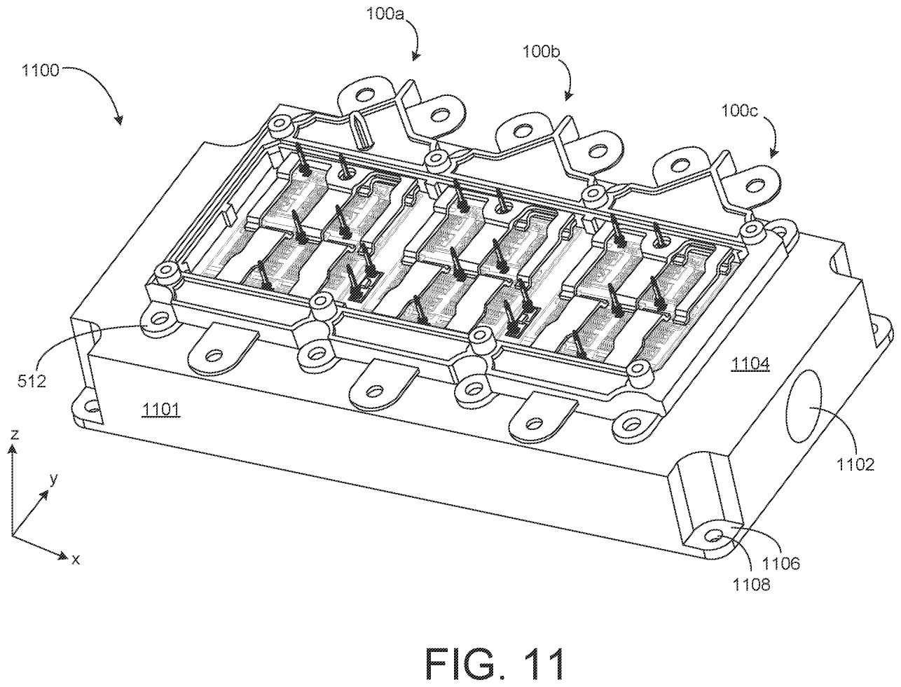

FIG. 11 shows a pictorial view of a fluid-cooled SSDC package 1100, in accordance with some implementations of the present disclosure. The fluid-cooled SSDC package 1100 includes a cooling unit 1101 that can be constructed according to the model illustrated in FIG. 10, to form a water jacket around the SSDC package 500, so as to expose a lower portion of the SSDC package 500 to a cooling fluid to remove heat from the metal base plate 510. A coolant inlet 1102, corresponding to the coolant inlet 1002, is shown at the right end of the cooling unit 1101. In some implementations, the cooling unit 1101 can be constructed of a thermally conductive material, e.g., a metal, to provide additional heat dissipation. In some implementations, the SSDC package 500, attached to the metal base plate 510, can be set into a cutout in the top surface 1104 of the cooling unit 1101. The cooling unit 1101 can further include corner cutouts 1106 and holes 1108. The cooling unit 1101 can be installed by inserting fasteners, e.g., screws, through the holes 1108 rather than installing the SSDC package 500 directly using the tabs 512.

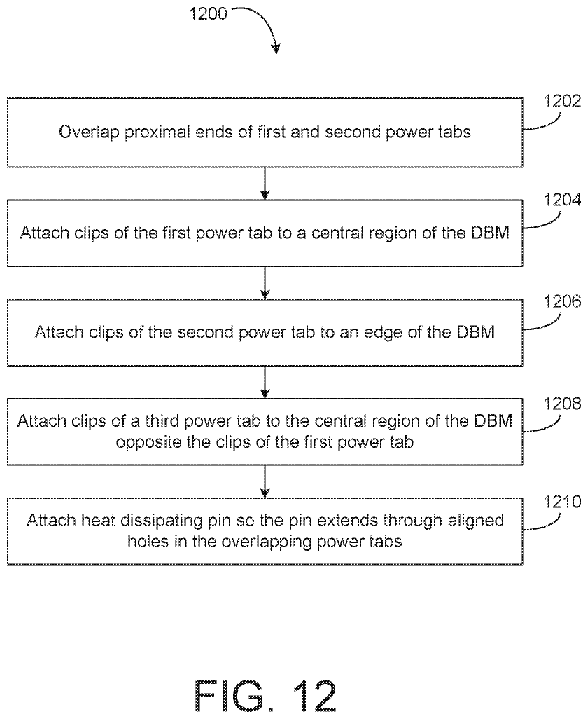

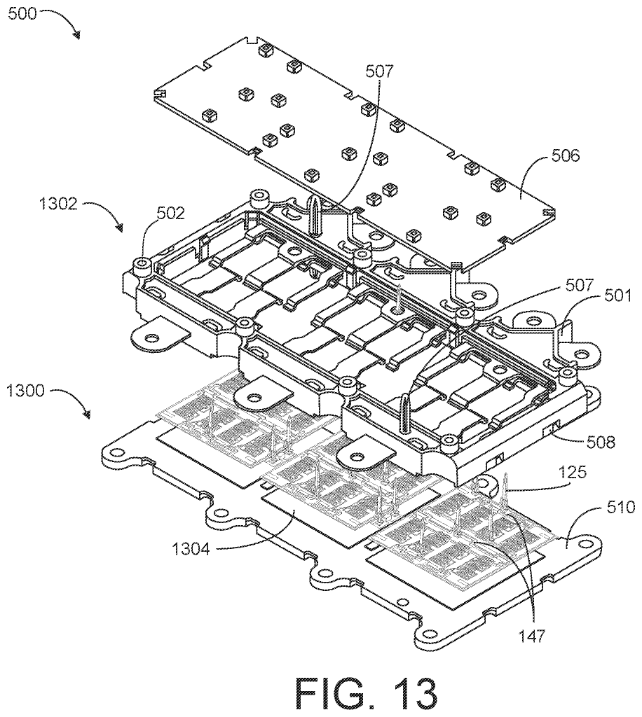

FIG. 12 is a flow chart illustrating a method 1200 for fabricating and packaging a power module 100, in accordance with some implementations of the present disclosure. Operations 1202-1210 of the method 1200 can be carried out to form the power module 100 and the SSDC package 500, according to some implementations as described below, with reference to FIGS. 1, 2A, 2B, 3A, 3B, 4, 5A, 5B, 6A, 6B, 7, 8, 9A, 9B, 10, and 11 as described above, and with reference to FIG. 13 as described below. Operations of the method 1200 can be performed in a different order, or not performed, depending on specific applications. It is noted that the method 1200 may not produce a complete power module 100 or a complete SSDC package 500. Accordingly, it is understood that additional processes can be provided before, during, or after method 1200, and that some of these additional processes may be briefly described herein.

At 1202, the method 1200 includes overlapping proximal ends of the first power tab 120 and the second power tab 122. This step can be performed in conjunction with fabricating the plastic case 501 of the SSDC package 500, as described below. Overlapping the proximal ends of the first and second power tabs 120 and 122, respectively, can include aligning a first hole in the first power tab 120 with a second hole in the second power tab 122 to create the aligned opening 150. The first power tab 120, the second power tab 122, and the third power tab 124 can all be insert molded into the plastic case 501. By incorporating the power tabs as integral parts of the plastic case 501, the desired orientation of the power tabs with respect to one another and the DBM 102 can be fixed. In addition, the desired positions of the clips 138, 140, and 142 will automatically be aligned so as to connect with, e.g., land on, the solder pads 147 of the DBM 102.

At 1204, the method 1200 includes attaching, e.g., coupling, clips 138 at a distal end of the first power tab 120 to the central region 144 of the DBM 102 so as to overlay the clips 138 above circuitry on the underlying DBM 102.

At 1206, the method 1200 includes attaching, e.g., coupling, clips 140 of the second power tab 122 to the end region 146 of the DBM 102.

At 1208, the method 1200 includes attaching, e.g., coupling, clips 142 at a distal end of the third power tab 124 to the central region 144 of the DBM 102.

Operations 1204, 1206, and 1 1208 can occur automatically as the plastic case 501 is lowered onto the metal base plate 510, as described below.

At 1210, the method 1200 includes attaching a heat dissipating pin 125 to extend through aligned holes in the overlapping first and second power tabs 120 and 122. The heat dissipating pins 125 can be attached to the DBM 102 and can extend through the aligned holes in the plastic case 501, as shown in FIG. 13.

FIG. 13 is an exploded view of the SSDC package 500, in accordance with some implementations of the present disclosure. FIG. 13 illustrates assembly of the power modules 100 into the SSDC package 500. The SSDC package 500 can be formed in three layers. In some implementations, a bottom layer 1300 can include the metal base plate 510, a pre-formed solder layer 1304, and the DBMs 102 for each power module 100. A middle layer 1302 can include the plastic case 501 and the power tabs 120, 122, and 124. The lid 506 can serve as the upper layer.

Starting with the bottom layer 1300, the pre-formed solder layer 1304 can be deposited onto the metal base plate 510, and patterned to fit the dimensions of the DBMs 102. The DBMs 102 can then be placed onto the pre-formed solder layer 1304 and heated, e.g., cured, to melt the pre-formed solder layer 1304 and also the solder pads 147. While the solder is soft, the plastic case 501 can be lowered onto the metal base plate 510 using the alignment pins 507 as a guide. It is noted that the plastic case 501 includes the power tabs 120, 122, and 124 as embedded elements for each of the three power modules 100. As the plastic case 501 is lowered onto the metal base plate 510, the power tabs 120, 122, and 124 will make electrical contact with the solder pads 147 in the central region 144 and the end region 146 of the DAP 108. The plastic case 501 can then be secured to the metal base plate 510 using the clips 508. Upon cooling, the DBMs 102 will be secured to the base plate 510, and the power tabs 120, 122, and 124 will be coupled to the electronic devices, e.g., the chip assemblies 110, on the DBM 102 via the solder pads 147.

Finally, the lid 506 can be lowered onto the plastic case 501 using the alignment pins 507 as a guide. The lid 506 can be secured using the fasteners 502, e.g., thumbscrews. The heat dissipating pins 125 extend through all of the layers including the lid 506, in which machined holes are formed that align with the positions of the heat dissipating pins 125.

As described above, various implementations of power modules 100 housed in an SSDC package 500 can improve performance of the power modules 100 while increasing heat dissipation of the SSDC package 500. A mini-heart design that overlaps positive and negative power tabs and routes high currents through clips of the power tabs can lower stray inductance and thermal resistance relative to a design that relies on a current path within the conductive layers of the DBM 102. The power tabs can be incorporated into the SSDC package 500, and can be cooled by a heat sink in the base plate 510 of the SSDC package 500. A water jacket can be added to the base plate 510 to provide additional cooling.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a direct bonded metal substrate;
a first power tab electrically coupled to the direct bonded metal substrate;
a second power tab electrically coupled to the direct bonded metal substrate;
a distal end of the first power tab aligned with a first longitudinal axis; and
a distal end of the second power tab aligned with a second longitudinal axis non-parallel to the first longitudinal axis, the first power tab having a proximal end overlapping a proximal end of the second power tab, wherein the distal end of the first power tab does not overlap the distal end of the second power tab.

2. The apparatus of claim 1, further comprising a heat transfer mechanism coupled to the direct bonded metal substrate.

3. The apparatus of claim 1, further comprising at least two semiconductor dies electrically coupled via a wire bond or a clip.

4. The apparatus of claim 1, further comprising an output tab electrically coupled to the direct bonded metal substrate.

5. The apparatus of claim 4 wherein, in operation, current flows from the first power tab to the output tab and from the output tab to the second power tab without flowing through the direct bonded metal substrate.

6. The apparatus of claim 1, further comprising heat dissipating pins that are oriented perpendicular to a plane of the direct bonded metal substrate and a plane of the first power tab and the second power tab.

7. The apparatus of claim 1, wherein a thickness of the first power tab and the second power tab is about three times greater than a thickness of a current path within a conductive layer of the direct bonded metal substrate.

8. The apparatus of claim 1, further comprising a first opening in the distal end of the first power tab and a second opening in the distal end of the second power tab.

9. The apparatus of claim 1, wherein a perimeter of the first power tab and the second power tab forms a heart shape.

10. An apparatus, comprising:
a direct bonded metal substrate;
a metal base plate attached to a bottom layer of the direct bonded metal substrate;
an array of heat dissipating pins attached to the metal base plate;
a first metal tab and a second metal tab coupled to the direct bonded metal substrate, the first metal tab oriented in a transverse direction with respect to the second metal tab; and
a plastic case surrounding a top layer of the direct bonded metal substrate.

11. The apparatus of claim 10, wherein the plastic case is attached to the metal base plate without screws.

12. The apparatus of claim 10, further comprising power tabs extending over the direct bonded metal substrate.

13. The apparatus of claim 10, wherein the first metal tab includes a negative terminal, and the second metal tab includes a positive terminal, and further comprising a third metal tab including an output terminal opposite the first metal tab and the second metal tab.

14. The apparatus of claim 13, wherein the apparatus is configured for current to flow from the positive terminal to the output terminal and back to the negative terminal via a central region of the direct bonded metal substrate.

15. The apparatus of claim 10, wherein the first metal tab is oriented at a right angle with respect to the second metal tab.

16. A method, comprising:
overlapping proximal ends of a first power tab and a second power tab
coupling clips of the first power tab to a central region of a substrate;
coupling clips of the second power tab to an edge region of the substrate; and
coupling clips of a third power tab to the central region of the substrate.

17. The method of claim 16, wherein the first power tab, the second power tab, and the third power tab are configured as integral elements of a plastic case.

18. The method of claim 17, wherein coupling the clips of the first power tab and the clips of the third power tab to a central region of the substrate comprises overlaying the clips above circuitry on the substrate by positioning the plastic case relative to the substrate.

19. The method of claim 16, wherein the overlapping includes aligning a first hole in the first power tab with a second hole in the second power tab to produce aligned first and second holes.

20. The method of claim 19, further comprising attaching a heat dissipating pin to the substrate, wherein the heat dissipating pin extends through the aligned first and second holes.
